(19) United States
(12) Patent Application Publication
(10) Pub. No.: US 2019/0123102 A1
(43) Pub. Date: Apr. 25, 2019

(54) NON-VOLATILE MEMORY DEVICE

(71) Applicant: Samsung Electronics Co., Ltd., Suwon-si (KR)

(72) Inventors: Si-Ho SONG, Suwon-si (KR); II Mok PARK, Seoul (KR); Kwang-Woo LEE, Hwaseong-si (KR); Se Gab KWON, Seoul (KR)

(73) Assignee: Samsung Electronics Co., Ltd., Suwon-si (KR)

(21) Appl. No.: 15/967,869

(22) Filed: May 1, 2018

(30) Foreign Application Priority Data
Oct. 23, 2017 (KR) 10-2017-0137102

(51) Int. Cl. H01L 27/24; H01L 45/00; H01L 27/22; H01L 43/08; H01L 43/02; H01L 43/10; H01F 10/32

(52) U.S. Cl. CPC H01L 27/2427; H01F 10/3254; H01L 27/224; H01L 45/1253; H01L 27/2481; H01L 45/08; H01L 45/06; H01L 43/08; H01L 45/146; H01L 45/148; H01L 45/144; H01L 43/02; H01L 43/10; H01L 45/143; H01L 45/1233

(57) ABSTRACT

A non-volatile memory device includes a substrate, a first electrode on the substrate, a second electrode on the substrate, a selection layer between the first electrode and the second electrode, and a memory layer contacting any one of the first electrode and the second electrode. The first electrode has a first width in a first direction. The second electrode is spaced apart from the first electrode in a second direction perpendicular to the first direction. The second electrode has a second width in the first direction. The selection element layer includes a first doped layer that contacts the first electrode. The first doped layer includes an impurity at a first concentration. The selection element layer includes a second doped layer that contacts the second electrode. The second doped layer includes the impurity at a second concentration lower than the first concentration.

This application claims the benefit of Korean Patent Application No. 10-2017-0137102, filed on Oct. 23, 2017, in the Korean Intellectual Property Office, the disclosure of which is incorporated herein in its entirety by reference.

### BACKGROUND

### 1. Technical Field

The present disclosure relates to a non-volatile memory device.

### 2. Description of Related Art

Generally, a semiconductor memory device is categorized into a volatile memory device of which stored information is lost upon interruption of power supply, and a non-volatile memory device of which stored information can be continuously retained even with the interruption of power supply. For the non-volatile memory device, a flash memory device having a stacked gate structure is mainly adopted. Meanwhile, a variable resistance memory device has been recently suggested as a new non-volatile memory device that will replace the flash memory device.

Because the semiconductor device is highly integrated, the variable resistance memory device of a cross point structure is being developed.

### SUMMARY

Inventive concepts relate to a non-volatile memory device which enhances reliability by reducing a difference in voltages applied with bi-directional electrical currents flowing in a selection element.

According some example embodiments, a non-volatile memory device includes a substrate, a first electrode on the substrate, a second electrode on the substrate, a selection element layer between the first electrode and the second electrode, and a memory layer contacting any one of the first electrode and the second electrode. The first electrode has a first width in a first direction. The second electrode is spaced apart from the first electrode in a second direction perpendicular to the first direction. The second electrode has a second width in the first direction. The selection element layer includes a first doped layer and a second doped layer. The first doped layer contacts the first electrode and includes an impurity at a first concentration. The second doped layer contacts the second electrode and includes the impurity at a second concentration. The second concentration is in a range that is greater than or equal to zero and lower than the first concentration.

According to some example embodiments, a non-volatile memory device includes a substrate, a first electrode on the substrate, a second electrode on the substrate, and a selection element layer between the first electrode and the second electrode. The first electrode has a first width in a first direction. The second electrode is spaced apart from the first electrode in a second direction perpendicular to the first direction. The second electrode includes a second width in the first direction that is narrower than the first width. The selection element layer includes a first doped layer and a second doped layer. The first doped layer contacts the first electrode. The first doped layer includes an impurity of a first concentration. The second doped layer contacts the second electrode. The second doped layer includes the impurity at a second concentration. The second concentration is in a range that is greater than or equal to 0 and lower than the first concentration.

According to some example embodiments, a non-volatile memory device includes a substrate, a first electrode on the substrate, a second electrode on the substrate, and a selection element layer between the first electrode and the second electrode. The first electrode has a first width in a first direction. The first electrode includes silicon (Si) at a first concentration. The second electrode is spaced apart from the first electrode in a second direction perpendicular to the first direction. The second electrode has a second width in the first direction that is narrower than the first width. The second electrode includes silicon (Si) at a second concentration that is lower than the first concentration.

Feature and effects of some example embodiments are not limited to those mentioned above and will be clearly understood to those skilled in the art based on the description provided below.

### BRIEF DESCRIPTION OF THE DRAWINGS

The above and other features and effects of inventive concepts will become more apparent to those of ordinary skill in the art by describing some example embodiments with reference to the accompanying drawings, in which:

FIG. 1 is an example circuit view provided to explain a memory cell array of a non-volatile memory device according to some example embodiments;

FIG. 2 is a layout view schematically illustrating a memory cell array of a non-volatile memory device according to some example embodiments;

FIG. 3 is a cross sectional view taken along line A-A of FIG. 2;

FIG. 4 is a cross sectional view taken along line B-B of FIG. 2;

FIG. 5 is a view enlarging a section P1 of FIG. 3;

FIG. 6 is a view provided to explain a non-volatile memory device according to some example embodiments;

FIG. 7 is a view provided to explain a non-volatile memory device according to some example embodiments;

FIG. 8 is a cross sectional view provided to explain a non-volatile memory device according to some example embodiments;

FIG. 9 is a view enlarging a section P2 of FIG. 8;

FIG. 10 is a view provided to explain a non-volatile memory device according to some example embodiments;

FIG. 11 is a view provided to explain a non-volatile memory device according to some example embodiments;

FIG. 12 is a cross sectional view provided to explain a non-volatile memory device according to some example embodiments;

FIG. 13 is a view enlarging a section P3 of FIG. 12;

FIG. 14 is a cross sectional view provided to explain a non-volatile memory device according to some example embodiments;

FIG. 15 is a layout view schematically illustrating a memory cell array of a non-volatile memory device according to some example embodiments;

FIG. 16 is a cross sectional view taken along line A-A of FIG. 15; and

FIG. 17 is a cross sectional view taken along line B-B of FIG. 15.

### DETAILED DESCRIPTION

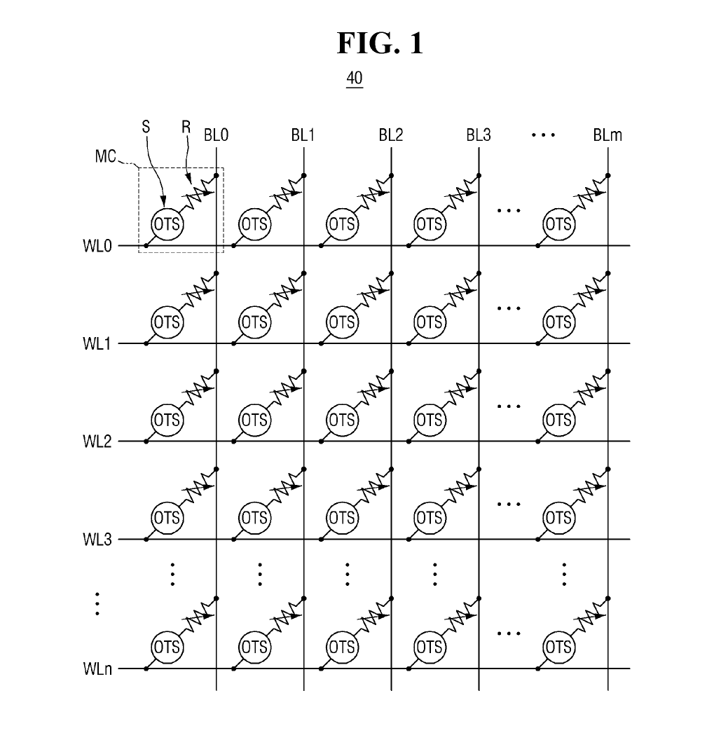

Hereinafter, a non-volatile memory device according to some example embodiments will be described with reference to FIG. 1 to FIG. 5.

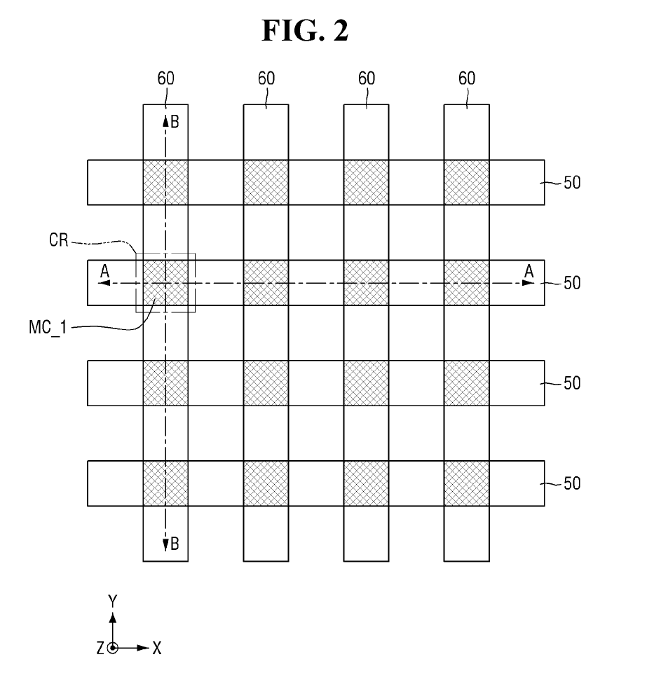

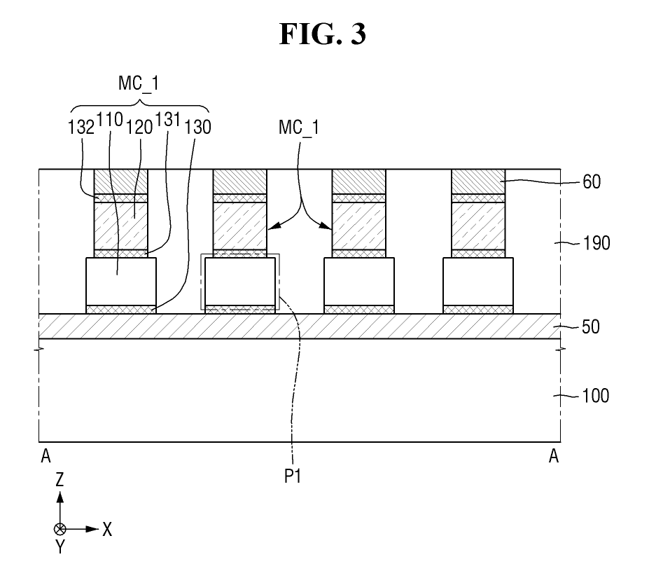

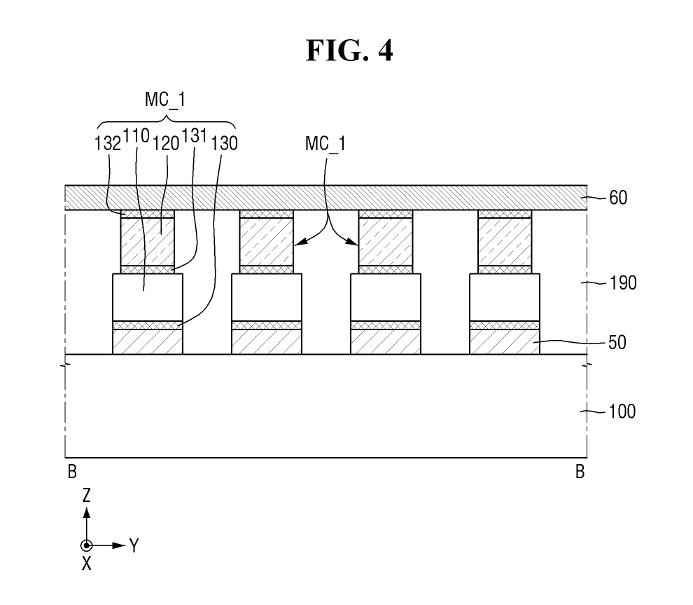

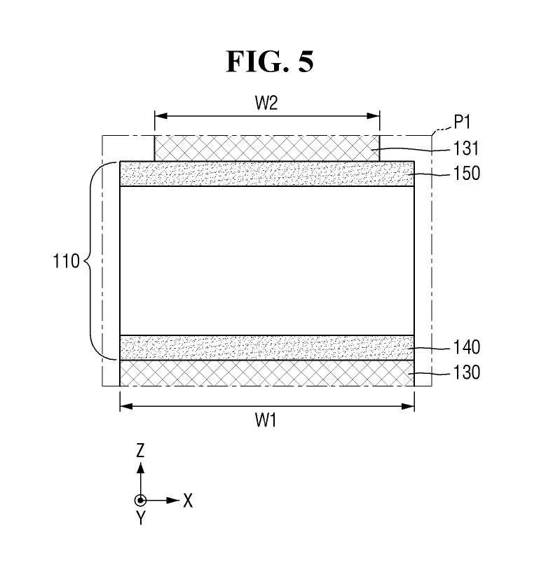

FIG. 1 is an example circuit view provided to explain a memory cell array of a non-volatile memory device according to some example embodiments. FIG. 2 is a layout view schematically illustrating a memory cell array of a non-volatile memory device according to some example embodiments. FIG. 3 is a cross sectional view taken along line A-A of FIG. 2. FIG. 4 is a cross sectional view taken along line B-B of FIG. 2. FIG. 5 is a view enlarging a section P1 of FIG. 3.

Referring to FIG. 1, the memory cell array 40 may be a two-dimensional memory. When the memory cell array 40 is composed of (or includes) multi-layers, the memory cell array 40 may be a three-dimensional memory.

The memory cell array 40 may include a plurality of word lines WL0-WLn, a plurality of bit lines BL0-BLm, and a plurality of memory cells MC. The number of the word lines WL, the number of the bit lines BL, and the number of the memory cells MC may be variously modified according to an embodiment. Further, a set of the memory cells that can be accessed by a same word line simultaneously may be defined as a page.

In the non-volatile memory device according to some example embodiments, each of the plurality of memory cells MC may include a variable resistance element R and a selection element S. Herein, the variable resistance element R may be referred to as a variable resistor (alternatively, variable resistance material), and the selection element S may be referred to as a switching element.

In the non-volatile memory device according to some example embodiments, the selection element S may be an ovonic threshold switch (OTS) selector including a chalcogenide compound.

For example, the variable resistance element R may be connected between one of the plurality of bit lines BL0-BLm and the selection element S, and the selection element S may be connected between the variable resistance element R and one of the plurality of word lines WL0-WLn.

However, inventive concepts are not limited thereto. That is, in some example embodiments, the selection element S may be connected between one of the plurality of bit lines BL0-BLm and the variable resistance element R, and the variable resistance element R may be connected between the selection element R and one of the plurality of word lines WL0-WLn.

The selection element S may be connected between any one of the plurality of word lines WL0-WLn and the variable resistance element R, and may control the current supply to the variable resistance element R according to a voltage applied to the connected word line and bit line.

Referring to FIG. 2 to FIG. 5, the non-volatile memory device according to some example embodiments may include a plurality of first conductive lines 50, a plurality of second conductive lines 60, and a plurality of first memory cells MC_1.

The plurality of first conductive lines 50 and the plurality of second conductive lines 60 may be formed on a substrate 100. The plurality of first conductive lines 50 may be formed to be spaced apart from the plurality of second conductive lines 60.

The plurality of first conductive lines 50 may extend in parallel to one another in a first direction X. The plurality of second conductive lines 60 may extend in parallel to one another in a third direction Y intersecting with the first direction X.

FIG. 2 depicts that the first direction and the third direction are intersecting with each other by exemplifying the first direction as the X direction and the third direction as the Y direction, but inventive concepts are not limited thereto. That is, the first direction and the third direction are in any directions as long as these are intersecting with each other.

Each of the plurality of first conductive lines 50 and the plurality of second conductive lines 60 may be a plurality of word lines or a plurality of bit lines.

In some example embodiments, the plurality of first conductive lines 50 may be the plurality of word lines, and the plurality of second conductive lines 60 may be the plurality of bit lines. In some example embodiments, the plurality of first conductive lines 50 may be the plurality of bit lines, and the plurality of second conductive lines 60 may be the plurality of word lines.

The substrate 100 may include a semiconductor wafer. In some example embodiments, the substrate 100 may include a semiconductor element such as Si and Ge, or a compound semiconductor such as SiC, GaAs, InAs, and InP. In some example embodiments, the substrate 100 may have a silicon on insulator (SOI) structure or a silicon-germanium on insulator (SGOI) structure. For example, the substrate 100 may include a buried oxide (BOX) layer. In some example embodiments, the substrate 100 may include a conductive region, for example, a well doped with impurity or a structure doped with impurity.

Although not illustrated, a structure including a plurality of gates, at least one interlayer insulating film, a plurality of contacts, and a plurality of wires may be interposed between the substrate 100 and the first conductive lines 50.

Each of the plurality of first conductive lines 50 and the plurality of second conductive lines 60 may be formed of metal, a conductive metal nitride, a conductive metal oxide, or a combination thereof.

In some example embodiments, each of the plurality of first conductive lines 50 and the plurality of second conductive lines 60 may be formed of tungsten (W), a tungsten nitride (WN), gold (Au), silver (Ag), copper (Cu), aluminum (Al), a titanium aluminum nitride (TiAlN), iridium (Ir), platinum (Pt), palladium (Pd), ruthenium (Ru), zirconium (Zr), rhodium (Rh), nickel (Ni), cobalt (Co), chrome (Cr), tin (Sn), zinc (Zn), an alloy thereof, or a combination thereof, but inventive concepts are not limited thereto.

In some example embodiments, each of the plurality of first conductive lines 50 and the plurality of second conductive lines 60 may include a metal film and a conductive barrier film covering at least a portion of the metal film. The conductive barrier film may be formed of, for example, titanium (Ti), a titanium nitride (TiN), tantalum (Ta), a tantalum nitride (TaN), or a combination thereof, but inventive concepts are not limited thereto.

The plurality of first conductive lines 50 and the plurality of second conductive lines 60 may be respectively formed in a plurality of stripe patterns intersecting with one another.

The plurality of first memory cells MC_1 (MC of FIG. 1) may be respectively formed at a plurality of intersection points CR between the plurality of first conductive lines 50 and the plurality of second conductive lines 60. The plurality of first memory cells MC_1 may form a cross point array structure.

The plurality of first memory cells MC_1 may be respectively arranged between the first conductive lines 50 and the second conductive lines 60 intersecting with each other, at the plurality of intersection points CR between the plurality of first conductive lines 50 and the plurality of second conductive lines 60.

The plurality of first memory cells MC_1 may be in pillar shapes extending in a second direction Z perpendicular to the first direction X and the third direction Y. However, inventive concepts are not limited thereto.

Referring to FIG. 2 to FIG. 4, a cross section on X-Y plane of the plurality of first memory cells MC_1 is roughly illustrated to be a rectangle shape, but inventive concepts are not limited thereto, and various shapes of cross-sectional structures may be obtained.

For example, a cross section on X-Y plane of the plurality of first memory cells MC_1 may have various shapes such as semicircle, semi-oval, trapezoid, triangle, and so on.

Each of the plurality of first memory cells MC_1 may store digital information. The plurality of first memory cells MC_1 may store digital information with a resistance change between various resistance states including a high resistance state and a low resistance state. Each of the plurality of first memory cells MC_1 may include at least one material layers different from each other.

Each of the plurality of first memory cells MC_1 may include a first selection element layer 110, a first memory layer 120, a first electrode 130, a second electrode 131, and a third electrode 132.

The first electrode 130 may be arranged on the substrate 100. The first electrode 130 may be connected with one of the plurality of first conductive lines 50, for example.

The first electrode 130 may include metal such as tungsten (W), platinum (Pt), palladium (Pd), rhodium (Rh), ruthenium (Ru), iridium (Tr), copper (Cu), aluminum (Al), titanium (Ti), tantalum (Ta), and so on. Alternatively, the first electrode 130 may include a metal nitride or a metal silicon nitride such as a titanium nitride (TiNx), a titanium silicon nitride (TiSiNx), a tungsten nitride (WNx), a tungsten silicon nitride (WSiNx), a tantalum nitride (TaNx), a tantalum silicon nitride (TaSiNx), a zirconium nitride (ZrNx), a zirconium silicon nitride (ZrSiNx), and so on. Alternatively, the first electrode 130 may include conductive oxide of the aforementioned material.

The second electrode 131 may be arranged above the first electrode 130 to be spaced apart therefrom in the second direction Z. That is, the first electrode 130 may be arranged closer to the substrate 100 than the second electrode 131. The second electrode 131 may be electrically connected with the first selection element layer 110 and the first memory layer 120, respectively.

The second electrode 131 may include a same material as that of the first electrode 130. However, inventive concepts are not limited thereto. That is, in some example embodiments, the second electrode 131 may include a material different from the first electrode 130 from among the example materials included in the above-described first electrode 130.

Referring to FIG. 5, a first width W1 of the first electrode 130 in the first direction X may be wider than a second width W2 of the second electrode in the first direction X. Accordingly, a resistance value of the second electrode 131 may be greater than a resistance value of the first electrode 130.

However, inventive concepts are not limited thereto. That is, in some example embodiments, when the width of the first electrode 130 in the first direction X and the width of the second electrode 131 in the first direction X are the same, a concentration of silicon (Si) included in the second electrode 131 may be higher than a concentration of silicon (Si) included in the first electrode 130. Accordingly, the resistance value of the second electrode 131 may be greater than the resistance value of the first electrode 130.

In addition, in some example embodiments, when the width of the first electrode 130 in the first direction X and the width of the second electrode 131 in the first direction X are the same, a concentration of nitrogen (N) included in the second electrode 131 may be higher than a concentration of nitrogen (N) included in the first electrode 130. Accordingly, the resistance value of the second electrode 131 may be greater than the resistance value of the first electrode 130.

Referring to FIG. 3 and FIG. 4, the third electrode 132 may be arranged above the second electrode 131 to be spaced apart therefrom in the second direction Z. The third electrode 132 may be connected with one of the plurality of second conductive lines 60, for example.

Like the first electrode 130, the third electrode 132 may include metal such as tungsten (W), platinum (Pt), palladium (Pd), rhodium (Rh), ruthenium (Ru), iridium (Ir), copper (Cu), aluminum (Al), titanium (Ti), tantalum (Ta), and so on. Alternatively, the third electrode 132 may include a metal nitride or a metal silicon nitride such as a titanium nitride (TiNx), a titanium silicon nitride (TiSiNx), a tungsten nitride (WNx), a tungsten silicon nitride (WSiNx), a tantalum nitride (TaNx), a tantalum silicon nitride (TaSiNx), a zirconium nitride (ZrNx), a zirconium silicon nitride (ZrSiNx), and so on. Alternatively, the third electrode 132 may include a conductive oxide of the aforementioned material.

The first memory layer 120 may be arranged between the second electrode 131 and the third electrode 132. The first memory layer 120 may be in contact with the second electrode 131. The first memory layer 120 may be formed more adjacent to the third electrode 132 rather than to the first electrode 130. The first memory layer 120 may be electrically connected with the second electrode 131 and the third electrode 132.

Although FIG. 3 and FIG. 4 depict that the first selection element layer 110 is arranged more adjacent to the substrate 100 than the first memory layer 120, inventive concepts are not limited thereto. That is, in some example embodiments, the first memory layer 120 may be arranged more adjacent to the substrate 100 than the first selection element layer 110.

The first memory layer 120 may include a resistance change layer in which the resistance varies according to the electrical field.

In some example embodiments, when the first memory layer 120 includes a transition metal oxide, the non-volatile memory device of the present disclosure may be a resistance random access memory (RRAM).

In some example embodiments, when the first memory layer 120 is formed of a phase change material in which the resistance varies according to the temperature, the non-volatile memory device of the present disclosure may be a phase change RAM (PRAM).

In some example embodiments, when the first memory layer 120 has a magnetic tunnel junction (MTJ) structure including two electrodes formed of a magnetic material, and a dielectric material interposed between the two magnetic electrodes, the non-volatile memory device of the present disclosure may be a magnetic RAM (MRAM).

In some example embodiments, the first memory layer 120 may be formed of various forms of compounds. In some example embodiments, the first memory layer 120 may be formed of a material in which impurity is added to various forms of compounds. In some example embodiments, the first memory layer 120 may include a resistance change layer, and at least one barrier film and/or at least one conductive film covering at least a portion of the resistance change layer.

When the first memory layer 120 is formed of a transition metal oxide, the transition metal oxide may include at least one metal selected from tantalum (Ta), zirconium (Zr), titanium (Ti), hafnium (Hf), manganese (Mn), yttrium (Y), nickel (Ni), cobalt (Co), zinc (Zn), niobium (Nb), copper (Cu), iron (Fe), or chrome (Cr). For example, the transition metal oxide may be formed in a single layer or multi layers formed of at least one material selected from Ta₂O₅₋ₓ, ZrO₂₋ₓ, TiO₂₋ₓ, HfO₂₋ₓ, MnO₂₋ₓ, Y₂O₃₋ₓ, Nb₂O₅₋ₓ, CuO_{1-y}, or Fe₂O₃₋ₓ. In the materials described above, x and y may be respectively selected in a range of 0≤x≤1.5 and 0≤y≤0.5, but inventive concepts are not limited thereto.

When the first memory layer 120 is formed of a phase change material in which the resistance state changes with the Joule heat generated with the voltage applied to both ends, the phase change material may be formed of various types of materials such as compounds of two elements such as GaSb, InSb, InSe, SbTe, and GeTe, compounds of three elements such as GST(GeSbTe), GeBiTe, GaSeTe, InSbTe, SnSb₂Te₄, and InSbGe, and compounds of four elements such as AgInSbTe, (GeSn)SbTe, GeSb(SeTe), Te₈₁Ge₁₅Sb₂S₂ and so on. Further, in order to enhance the characteristics of the first memory layer 120, the phase change material described above may be doped with nitrogen (N), silicon (Si), carbon (C) or oxygen (O).

Further, when the first memory layer 120 has a MTJ structure, the MTJ structure may include a magnetized fixed layer, a magnetized free layer, and a tunnel barrier interposed therebetween. The tunnel barrier may be formed of an oxide of any one material selected from magnesium (Mg), titanium (Ti), aluminum (Al), an alloy of magnesium and zinc (MgZn), and magnesium boride (MgB), but inventive concepts are not limited thereto.

The first selection element layer 110 may be arranged between the first electrode 130 and the second electrode 131.

The selection element S of FIG. 1 may correspond to the first selection element layer 110, the first electrode 130, and the second electrode 131. The variable resistance element R of FIG. 1 may correspond to the first memory layer 120, the third electrode 132, and the second electrode 131.

The selection element (S of FIG. 1) including the first selection element layer 110, the first electrode 130, and the second electrode 131 may be an electrical current adjustment element that can control flows of the electrical currents. For example, the selection element S may control flows of the electrical currents so that the first memory layer 120 can be changed to an amorphous state or a crystalline state. That is, the selection element S may play a role of a switch of a memory, which changes the state of the first memory layer 120 to either on state or off state.

A width of the first selection element layer 110 in the first direction X may be the same as the first width W1 of the first electrode 130. However, inventive concepts are not limited thereto. That is, in some example embodiments, the width of the first selection element layer 110 in the first direction X may be the same as the second width W2 of the second electrode 131.

The first selection element layer 110 may include a first doped layer 140 and a second doped layer 150.

The first doped layer 140 may be arranged so as to be in contact with the first electrode 130. A width of the first doped layer 140 in the first direction X may be the same as the first width W1 of the first electrode 130. However, inventive concepts are not limited thereto.

The first doped layer 140 may include impurity of a first concentration, for example, at least one of silicon (Si), boron (B), carbon (C), nitrogen (N), phosphorus (P), arsenic (As), germanium (Ge), aluminum (Al), gallium (Ga), indium (In), antimony (Sb), and tellurium (Te).

The second doped layer 150 may be arranged so as to be in contact with the second electrode 131. A width of the second doped layer 150 in the first direction X may be the same as the first width W1 of the first electrode 130. However, inventive concepts are not limited thereto.

The second doped layer 150 may include impurity of a second concentration lower than the first concentration, for example, at least one of silicon (Si), boron (B), carbon (C), nitrogen (N), phosphorus (P), arsenic (As), germanium (Ge), aluminum (Al), gallium (Ga), indium (In), antimony (Sb), and tellurium (Te).

A first interlayer insulating film 190 may be formed on the substrate 100. The first interlayer insulating film 190 may surround sidewalls of the plurality of first memory cells MC_1 arranged between the first conductive lines 50 and the second conductive lines 60. The first interlayer insulating film 190 may include an oxide film, for example, at least one of a flowable oxide (FOX), tonen silazene (TOSZ), undoped silicate glass (USG), boro silicate glass (BSG), phospho silicate glass (PSG), borophospho silicate glass (BPSG), plasma enhanced tetra ethyl ortho silicate (PE-TEOS), fluoride silicate glass (FSG) and high density plasma (HDP). The first interlayer insulating film 190 may be a single layer, or may be a stack of a plurality of layers.

In the non-volatile memory device according to some example embodiments, the first width W1 of the first electrode 130 may be wider than the second width W2 of the second electrode 131, such that the resistance value of the second electrode 131 is greater than the resistance value of the first electrode 130. In addition, the first concentration of the impurity of the first doped layer 140 contacting the first electrode 130 may be higher than the second concentration of the impurity of the second doped layer 150 contacting the second electrode 131, such that the resistance value of the first doped layer 140 is greater than the resistance value of the second doped layer 150.

That is, the first doped layer 140 may be doped with more impurities than the second doped layer 150, such that the difference between the resistance value of the second electrode 131 and the resistance value of the first electrode 130 can be compensated.

The non-volatile memory device according to some example embodiments may equally maintain levels of voltages respectively applied when the electrical currents flow in the forward direction (a direction from the first electrode 130 to the second electrode 131), and when the electrical currents flow in the reverse direction (a direction from the second electrode 131 to the first electrode 130). Accordingly, the difference in the voltages applied with the bi-directional electrical currents flowing in the first selection element layer 110 is reduced, such that performance of the non-volatile memory device can be enhanced.

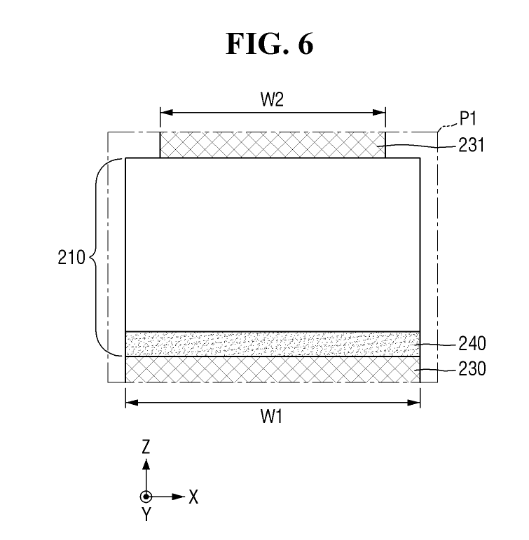

Hereinbelow, a non-volatile memory device according to some example embodiments will be described with reference to FIG. 6. The differences from the non-volatile memory device illustrated in FIG. 3 to FIG. 5 will be highlighted.

FIG. 6 is a view provided to explain a non-volatile memory device according to some example embodiments.

Referring to FIG. 6, a plurality of first memory cells MC_1 may include a first selection element layer 210, a first memory layer (120 of FIG. 3), a first electrode 230, a second electrode 231, and a third electrode (132 of FIG. 3).

The first selection element layer 210 may include a first doped layer 240 which is arranged so as to be in contact with the first electrode 230.

However, the first selection element layer 210 may not include another doped layer on a region which is in contact with the second electrode 231. That is, the second concentration of the impurity of the second doped layer 150 in FIG. 5 is 0.

In the non-volatile memory device according to some example embodiments, a difference between the resistance value of the second electrode 231 and the resistance value of the first electrode 230 may be compensated by adjusting a concentration of impurity doped on the first doped layer 240.

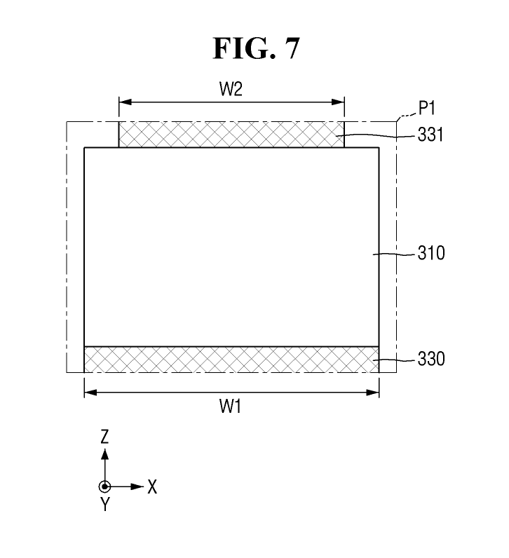

Hereinbelow, a non-volatile memory device according to some example embodiments will be described with reference to FIG. 7. The differences from the non-volatile memory device illustrated in FIG. 3 to FIG. 5 will be highlighted.

FIG. 7 is a view provided to explain a non-volatile memory device according to some example embodiments.

Referring to FIG. 7, a plurality of first memory cells MC_1 may include a first selection element layer 310, a first memory layer (120 of FIG. 3), a first electrode 330, a second electrode 331, and a third electrode (132 of FIG. 3).

The first selection element layer 310 may not include a separate doped layer on a region which is in contact with the first electrode 330 and a region which is in contact with the second electrode 331. That is, in FIG. 5, the first concentration of the impurity of the first doped layer 140 and the second concentration of the impurity of the second doped layer 150 are both 0.

A concentration of silicon (Si) included in the second electrode 331 may be lower than a concentration of silicon (Si) included in the first electrode 330. In addition, in some example embodiments, a concentration of nitrogen (N) included in the second electrode 331 may be lower than a concentration of nitrogen (N) included in the first electrode 330.

In the non-volatile memory device according to some example embodiments, the concentration of the silicon (Si) or nitrogen (N) doped on the second electrode 331 may be smaller than the concentration of the silicon (Si) or nitrogen (N) doped on the first electrode 330, such that the resistance value of the first electrode 330 and the resistance value of the second electrode 331 can be equally maintained.

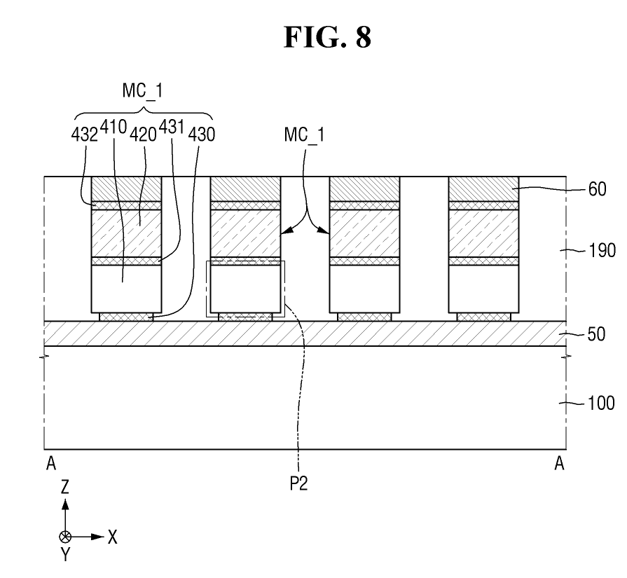

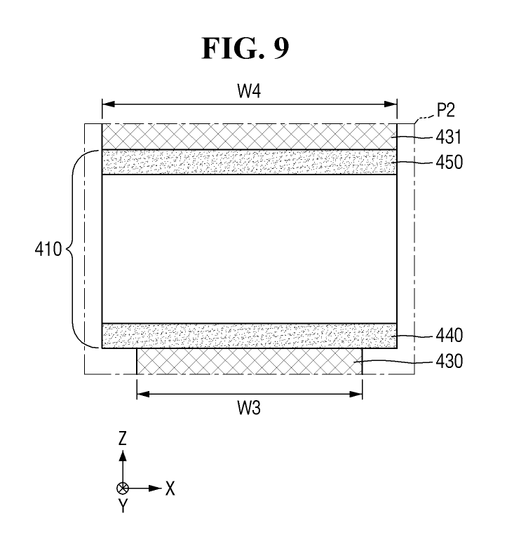

Hereinbelow, a non-volatile memory device according to some example embodiments will be described with reference to FIG. 8 and FIG. 9. The differences from the non-volatile memory device illustrated in FIG. 3 to FIG. 5 will be highlighted.

FIG. 8 is a cross sectional view provided to explain a non-volatile memory device according to some example embodiments. FIG. 9 is a view enlarging a section P2 of FIG. 8.

Referring to FIG. 8 and FIG. 9, a plurality of first memory cells MC_1 may include a first selection element layer 410, a first memory layer 420, a first electrode 431, a second electrode 430, and a third electrode 432.

A width of each of the first selection element layer 410, the first memory layer 420, and the third electrode 432 in the first direction X may be the same as a first width W4 of the first electrode 431 in the first direction X. However, inventive concepts are not limited thereto.

That is, the second electrode 430 may be arranged closer to the substrate 100 than the first electrode 431.

A second width W3 of the second electrode 430 in the first direction X may be narrower than the first width W4 of the first electrode 431 in the first direction X. Accordingly, the resistance value of the second electrode 430 may be greater than the resistance value of the first electrode 431.

A first concentration of impurity of a first doped layer 450 may be higher than a second concentration of impurity of a second doped layer 440.

In the non-volatile memory device according to some example embodiments, the first doped layer 450 may be doped with more impurities than the second doped layer 440, such that the difference between the resistance value of the second electrode 430 and the resistance value of the first electrode 431 can be compensated.

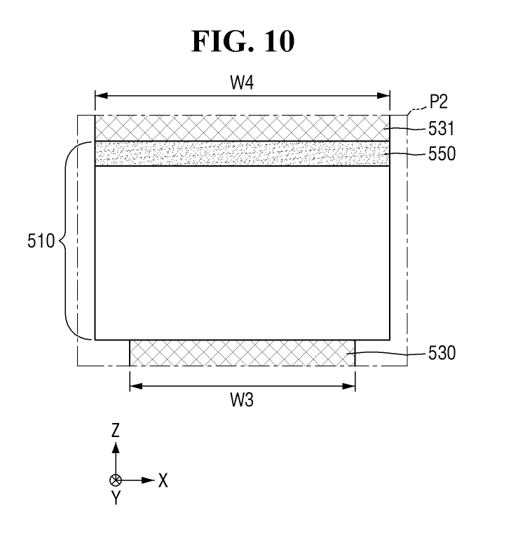

Hereinbelow, a non-volatile memory device according to some example embodiments will be described with reference to FIG. 10. The differences from the non-volatile memory device illustrated in FIG. 8 and FIG. 9 will be highlighted.

FIG. 10 is a view provided to explain a non-volatile memory device according to some example embodiments.

Referring to FIG. 10, a plurality of first memory cells MC_1 may include a first selection element layer 510, a first memory layer (420 of FIG. 8), a first electrode 531, a second electrode 530, and a third electrode (432 of FIG. 8).

The first selection element layer 510 may include a first doped layer 550 which is arranged so as to be in contact with the first electrode 531.

However, the first selection element layer 510 may not include another doped layer on a region which is in contact with the second electrode 530. That is, the second concentration of the impurity of the second doped layer 440 in FIG. 9 is 0.

In the non-volatile memory device according to some example embodiments, the difference between the resistance value of the second electrode 530 and the resistance value of the first electrode 531 may be compensated by adjusting the concentration of the impurity doped on the first doped layer 550.

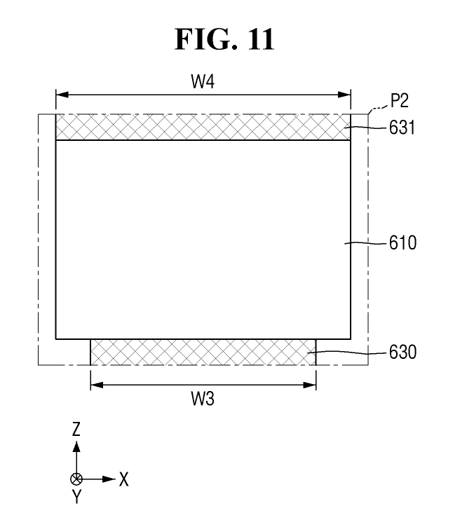

Hereinbelow, a non-volatile memory device according to some example embodiments will be described with reference to FIG. 11. The differences from the non-volatile memory device illustrated in FIG. 8 and FIG. 9 will be highlighted.

FIG. 11 is a view provided to explain a non-volatile memory device according to some example embodiments.

Referring to FIG. 11, a plurality of first memory cells MC_1 may include a first selection element layer 610, a first memory layer (420 of FIG. 8), a first electrode 631, a second electrode 630, and a third electrode (432 of FIG. 8).

The first selection element layer 610 may not include a separate doped layer on a region which is in contact with the first electrode 631 and a region which is in contact with the second electrode 630. That is, in FIG. 9, the first concentration of the impurity of the first doped layer 450 and the second concentration of the impurity of the second doped layer 440 are both 0.

A concentration of silicon (Si) included in the second electrode 630 may be lower than a concentration of silicon (Si) included in the first electrode 631. In addition, in some example embodiments, a concentration of nitrogen (N) included in the second electrode 630 may be lower than a concentration of nitrogen (N) included in the first electrode 631.

In the non-volatile memory device according to some example embodiments, the concentration of the silicon (Si) or nitrogen (N) doped on the second electrode 630 may be lower than the concentration of silicon (Si) or nitrogen (N) doped on the first electrode 631, such that the resistance value of the first electrode 631 and the resistance value of the second electrode 630 can be equally maintained.

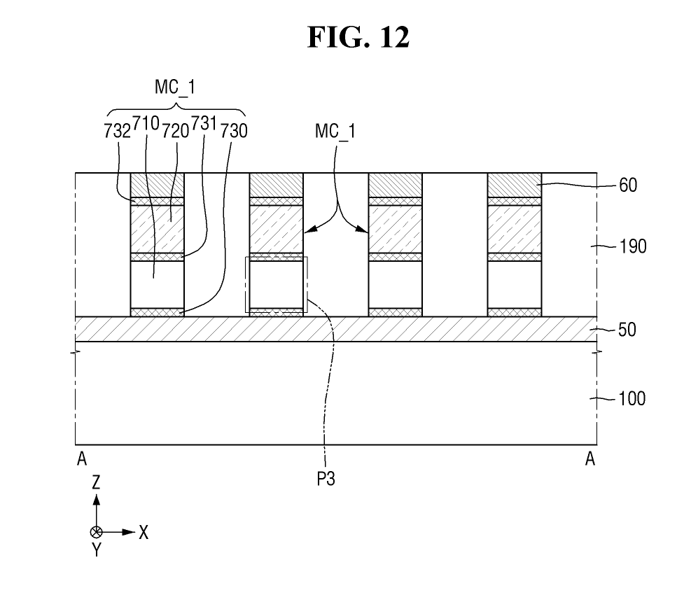

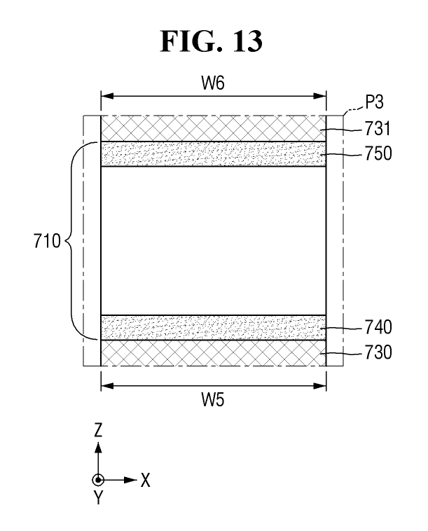

Hereinbelow, a non-volatile memory device according to some example embodiments will be described with reference to FIG. 12 and FIG. 13. The differences from the non-volatile memory device illustrated in FIG. 3 to FIG. 5 will be highlighted.

FIG. 12 is a cross sectional view provided to explain a non-volatile memory device according to some example embodiments. FIG. 13 is a view enlarging a section P3 of FIG. 12.

Referring to FIG. 12 and FIG. 13, a plurality of first memory cells MC_1 may include a first selection element layer 710, a first memory layer 720, a first electrode 730, a second electrode 731, and a third electrode 732.

A first width W5 of the first electrode 730 in the first direction X may be the same as a second width W6 of the second electrode 731 in the first direction X.

A width of each of the first selection element layer 710, the first memory layer 720, and the third electrode 732 in the first direction X may be the same as the first width W5 of the first electrode 730 and the second width W6 of the second electrode 731. However, inventive concepts are not limited thereto.

The first electrode 730 and the second electrode 731 may include materials different from each other. The first electrode 730 may include a material having a smaller resistance than that of the second electrode 731. For example, the first electrode 730 may include a titanium nitride (TiN), and the second electrode 731 may include a titanium silicon nitride (TiSiN).

In some example embodiments, the first electrode 730 may include a same material as that of the second electrode 731. In this case, a concentration of silicon (Si) or nitrogen (N) included in the second electrode 731 may be higher than a concentration of silicon (Si) or nitrogen (N) included in the first electrode 730.

In some example embodiments, when a concentration of impurity doped on a first doped layer 740 is lower than a concentration of impurity doped on a second doped layer 750, the first electrode 730 may include a material having a resistance greater than that of the second electrode 731. For example, the second electrode 731 may include a titanium nitride (TiN), and the first electrode 730 may include a titanium silicon nitride (TiSiN).

In some example embodiments, when the first electrode 730 includes the same material as that of the second electrode 731, and the concentration of the impurity doped on the first doped layer 740 is lower than the concentration of the impurity doped on the second doped layer 750, the concentration of the silicon (Si) or nitrogen (N) included in the first electrode 730 may be higher than the concentration of the silicon (Si) or nitrogen (N) included in the second electrode 731.

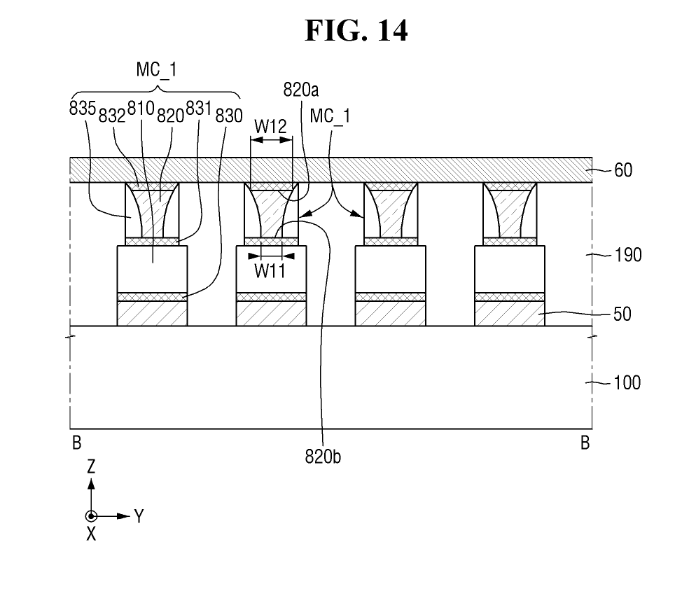

Hereinbelow, a non-volatile memory device according to some example embodiments will be described with reference to FIG. 14. The differences from the non-volatile memory device illustrated in FIG. 4 will be highlighted.

FIG. 14 is a cross sectional view provided to explain a non-volatile memory device according to some example embodiments.

Referring to FIG. 14, a plurality of first memory cells MC_1 may include a first selection element layer 810, a first memory layer 820, a first electrode 830, a second electrode 831, a third electrode 832, and a spacer 835.

The plurality of first memory cells MC_1 may further include the spacer 835 arranged along a sidewall of the first memory layer 820.

The spacer 835 may be arranged between the second conductive line 60 and the second electrode 831. The spacer 835 may be limitedly formed in a region where the first conductive line 50 and the second conductive line 60 are intersecting with each other.

The spacer 835 may include a silicon nitride or a silicon oxide, but not limited thereto.

Because the spacer 835 is formed in a manner in which it 835 is deposited into a liner shape and then only a sidewall portion is remained, an upper portion may be formed narrower than a lower portion. That is, a width of the spacer 835 may become narrower toward the upper portion.

The first memory layer 820 may be formed by filling at least a portion of a space defined by the spacer 835. Accordingly, a width of the first memory layer 820 may increase as it is farther away from the second electrode 831.

More specifically, a width of the first memory layer 820 in the third direction Y may increase as it is farther away from the second electrode 831.

The first memory layer 820 may include a first surface 820a and a second surface 820b facing each other. The first surface 820a of the first memory layer 820 may be adjacent to the third electrode 832, and the second surface 820b of the first memory layer 820 may be adjacent to the second electrode 831.

In this case, a width W12 of the first surface 820a of the first memory layer 820 in the third direction Y may be wider than a width W11 of the second surface 820b of the first memory layer 820 in the third direction Y.

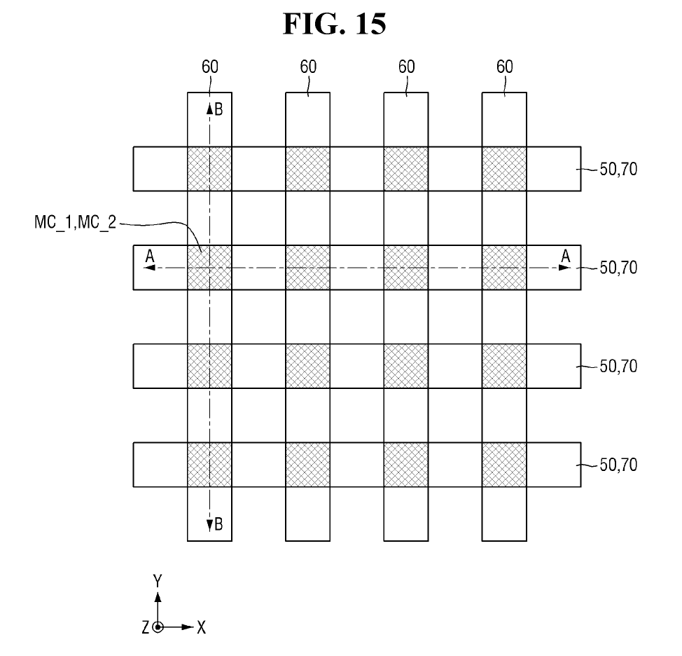

Hereinbelow, a non-volatile memory device according to some example embodiments will be described with reference to FIG. 15 to FIG. 17. The differences from the non-volatile memory device illustrated in FIG. 2 to FIG. 5 will be highlighted.

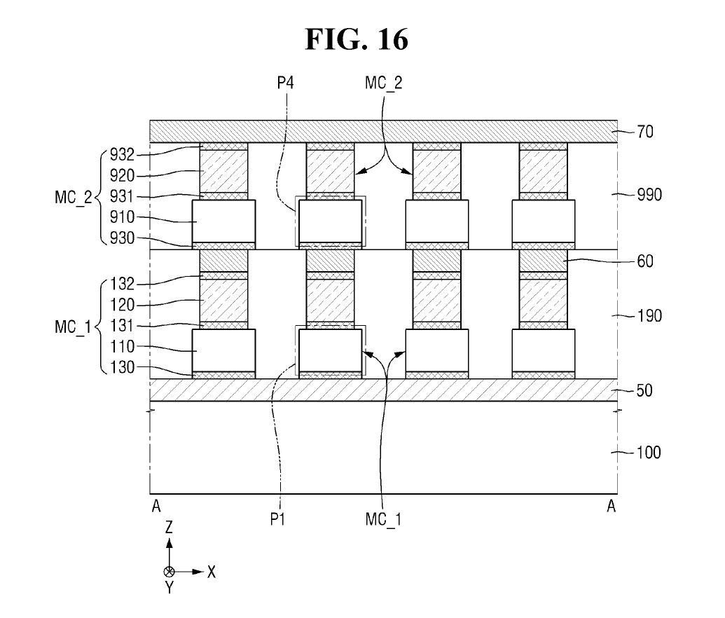

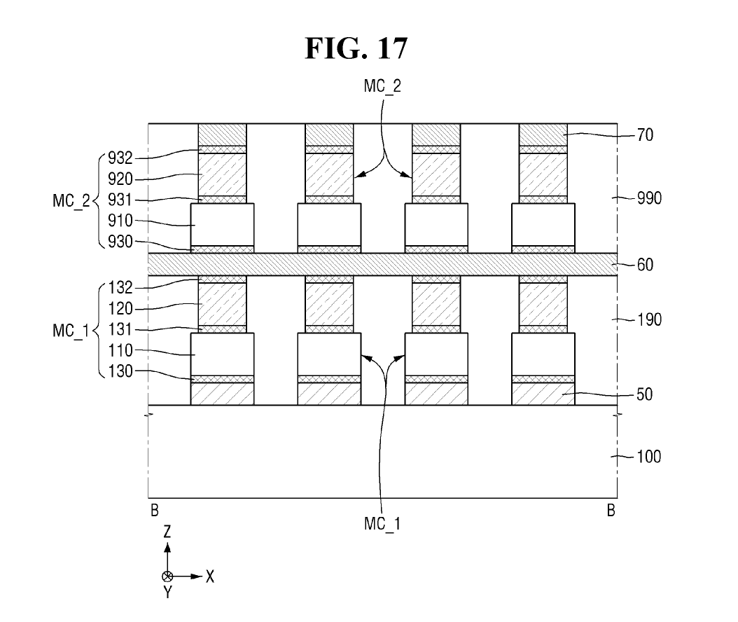

FIG. 15 is a layout view schematically illustrating a memory cell array of a non-volatile memory device according to some example embodiments. FIG. 16 is a cross sectional view taken along line A-A of FIG. 15. FIG. 17 is a cross sectional view taken along line B-B of FIG. 15.

For reference, the enlargement view of a section P1 of FIG. 16 may be any one of FIG. 5 to FIG. 7.

In addition, the enlargement view of the section P1 of FIG. 16 may be any one of FIG. 9 and FIG. 11. In this case, however, the width of the second electrode 131 in the first direction X may be wider than the width of the first electrode 130 in the first direction X.

In addition, the enlargement view of the section P1 of FIG. 16 may be FIG. 13. In this case, however, the width of the second electrode 131 in the first direction X may be the same as the width of the first electrode 130 in the first direction X.

A section P4 may have a same configuration and a same shape as those of the section P1.

Referring to FIG. 15 to FIG. 17, the non-volatile memory device according to some example embodiments may include a plurality of third conductive lines 70 and a plurality of second memory cells MC_2.

The plurality of third conductive lines 70 may be formed above the plurality of second conductive lines 60. The plurality of third conductive lines 70 may be formed to be spaced apart from the plurality of second conductive lines 60. The plurality of second conductive lines 60 may be arranged between the plurality of third conductive lines 70 and the plurality of first conductive lines 50.

The plurality of third conductive lines 70 may extend in parallel to one another in the first direction X.

Although FIG. 15 depicts that the plurality of first conductive lines 50 and the plurality of third conductive lines 70 extend in parallel to each other, and are orthogonal to a direction in which the plurality of second conductive lines 60 extend, inventive concepts are not limited thereto.

Each of the plurality of first conductive lines 50, the plurality of second conductive lines 60, and the plurality of third conductive lines 70 may be a plurality of word lines or a plurality of bit lines. In some example embodiments, each of the plurality of first conductive lines 50 and the plurality of third conductive lines 70 may be a plurality of bit lines, and each of the plurality of second conductive lines 60 may be common word lines. In some example embodiments, each of the plurality of first conductive lines 50 and the plurality of third conductive lines 70 may be a plurality of word lines, and each of the plurality of second conductive lines 60 may be common bit lines.

The plurality of first memory cells MC_1 may be respectively arranged at a plurality of intersection points between the plurality of first conductive lines 50 and the plurality of second conductive lines 60, and the plurality of second memory cells MC_2 may be respectively arranged at a plurality of intersection points between the plurality of second conductive lines 60 and the plurality of third conductive lines 70.

At the plurality of intersection points between the plurality of second conductive lines 60 and the plurality of third conductive lines 70, the plurality of second memory cells MC_2 may be respectively arranged between the second conductive lines 60 and the third conductive lines 70 which are intersecting with each other.

Each of the plurality of second memory cells MC_2 may be in a pillar shape extending in the second direction Z.

Each of the plurality of second memory cells MC_2 may include a second selection element layer 910, a second memory layer 920, a fourth electrode 930, a fifth electrode 931, and a sixth electrode 932.

The sixth electrode 932 and the fourth electrode 930 may be spaced apart from each other. The sixth electrode 932 may be connected with one of the plurality of third conductive lines 70, for example. The fourth electrode 930 may be connected with one of the plurality of second conductive lines 60, for example.

The second selection element layer 910 and the second memory layer 920 may be arranged between the sixth electrode 932 and the fourth electrode 930.

The second selection element layer 910 may be arranged between the sixth electrode 932 and the fourth electrode 930. For example, the second selection element layer 910 may be arranged more adjacent to the fourth electrode 930 rather than to the sixth electrode 932. The second selection element layer 910 may be electrically connected with the fourth electrode 930.

The second memory layer 920 may be arranged between the sixth electrode 932 and the second selection element layer 910. For example, the second memory layer 920 may be formed more adjacent to the sixth electrode 932 rather than to the fourth electrode 930. The second memory layer 920 may be electrically connected with the sixth electrode 932.

The fifth electrode 931 may be arranged between the second memory layer 920 and the second selection element layer 910. The fifth electrode 931 may be electrically connected with the second memory layer 920 and the second selection element layer 910, respectively.

The second memory layer 920 may include a resistance change layer in which the resistance varies according to the electrical field. The second memory layer 920 may include a transition metal oxide, or include a phase change material in which the resistance varies according to the temperature, or have a magnetic tunnel junction (MTJ) structure including two electrodes formed of a magnetic material, and a dielectric material interposed between the two magnetic electrodes.

A second interlayer insulating film 990 may be formed above the substrate 100. The second interlayer insulating film 990 may surround sidewalls of the plurality of second memory cells MC_2 arranged between the second conductive lines 60 and the third conductive lines 70.

Although some example embodiments have been explained above, but it should be understood that the example embodiments described above are only illustrative, and should not be construed as limiting. Example embodiments may be embodied in various different forms without departing from the spirit and scope of the claims.

What is claimed is:

1. A non-volatile memory device comprising:
a substrate;
a first electrode on the substrate, the first electrode having a first width in a first direction;
a second electrode on the substrate, the second electrode being spaced apart from the first electrode in a second direction that is perpendicular to the first direction, and the second electrode having a second width in the first direction; and
a selection element layer between the first electrode and the second electrode, the selection element layer including a first doped layer contacting the first electrode, and the first doped layer including an impurity at a first concentration, and
the selection element layer including a second doped layer contacting the second electrode, and the second doped layer including the impurity at a second concentration,
the second concentration being in a range that is greater than or equal to zero and lower than the first concentration; and
a memory layer contacting any one of the first electrode and the second electrode.

2. The non-volatile memory device of claim 1, wherein
the first width of the first electrode is wider than the second width of the second electrode, and
the first electrode and the second electrode include a same material as each other.

3. The non-volatile memory device of claim 2, wherein the first electrode is arranged closer to the substrate than the second electrode.

4. The non-volatile memory device of claim 3, wherein the second concentration is 0.

5. The non-volatile memory device of claim 2, wherein the second electrode is arranged closer to the substrate than the first electrode.

6. The non-volatile memory device of claim 1, wherein
the first width of the first electrode and the second width of the second electrode are the same as each other, and
a material of the first electrode is different than a material of the second electrode.

7. The non-volatile memory device of claim 6, wherein
the second electrode includes a titanium silicon nitride (Ti SiN), and
the first electrode comprises a titanium nitride (TiN).

8. The non-volatile memory device of claim 1, wherein a concentration of silicon (Si) included in the second electrode is higher than a concentration of silicon (Si) included in the first electrode.

9. The non-volatile memory device of claim 1, wherein a concentration of nitrogen (N) included in the second electrode is higher than a concentration of nitrogen (N) included in the first electrode.

10. The non-volatile memory device of claim 1, further comprising:
a spacer, wherein
the memory layer includes two sidewalls, and
the spacer is arranged along both of the two sidewalls of the memory layer.

11. A non-volatile memory device comprising:
a substrate;
a first electrode on the substrate, the first electrode having a first width in a first direction;
a second electrode on the substrate, the second electrode being spaced apart from the first electrode in a second direction perpendicular to the first direction, and the second electrode having a second width in the first direction that is narrower than the first width;
a selection element layer which between the first electrode and the second electrode,
the selection element including a first doped layer which contacting the first electrode, and the first doped layer including an impurity at a first concentration; and
a second doped layer contacting the second electrode, and the second doped layer including the impurity at a second concentration, the second concentration being in a range that is greater than or equal to zero and lower than the first concentration.

12. The non-volatile memory device of claim 11, wherein the first electrode and the second electrode include a same material as each other.

13. The non-volatile memory device of claim 11, wherein the first electrode is arranged closer to the substrate than the second electrode.

14. The non-volatile memory device of claim 11, wherein the second electrode is arranged closer to the substrate than the first electrode.

15. The non-volatile memory device of claim 14, wherein the second concentration is 0.

16. A non-volatile memory device comprising:
a substrate;
a first electrode on the substrate, the first electrode having a first width in a first direction, and the first electrode including silicon (Si) at a first concentration;
a second electrode on the substrate, the second electrode spaced apart from the first electrode in a second direction perpendicular to the first direction, the second electrode having a second width in the first direction that is narrower than the first width, and the second electrode including silicon (Si) at a second concentration lower than the first concentration; and
a selection element layer between the first electrode and the second electrode.

17. The non-volatile memory device of claim 16, wherein the first electrode is closer to the substrate than the second electrode.

18. The non-volatile memory device of claim 16, wherein the second electrode is closer to the substrate than the first electrode.

19. The non-volatile memory device of claim 16, wherein
the selection element layer includes a first doped layer,
the first doped layer contacts the first electrode, and
the first doped layer including an impurity at a third concentration.

20. The non-volatile memory device of claim 19, wherein
the selection element layer includes a second doped layer,
the second doped layer contacts the second electrode, and
the second doped layer includes the impurity at a fourth concentration that is lower than the third concentration.
